(19) United States
(12) Patent Application Publication
(10) Pub. No.: US 2010/0236809 A1
(43) Pub. Date: Sep. 23, 2010

(54) ERGONOMIC BED LOCATOR

(75) Inventors: David C. Newkirk, Lawrenceburg, IN (US); Dennis J. Gallant, Harrison, IN (US); Brian J. Hoffman, Lawrenceburg, IN (US); Steven R. Westerfeld, Holton, IN (US); Joseph H. Abel, New Palestine, IN (US)

Correspondence Address: HILL-ROM SERVICES, INC., Legal Dept., Mail Code K04, 1069 State Road 46 East, BATESVILLE, IN, 47006, US

(73) Assignee: HILL-ROM SERVICES, INC., Wilmington, DE (US)

(21) Appl. No.: 12/408,365

(22) Filed: Mar. 20, 2009

(51) Int. Cl. H05K 5/00

(52) U.S. Cl. 174/53

(57) ABSTRACT

A locator can comprise a protective cover and a plurality of service outlets. The protective cover can be configured to be mounted on a wall. The protective cover can include a lower edge. The lower edge can be positioned at a height of less than about 10 inches above a floor. The plurality of service outlets can be coupled to the protective cover and can be positioned at a height of over 22.5 inches above the floor

### BACKGROUND OF THE DISCLOSURE

This disclosure relates generally to locators. More particularly, but not exclusively, one illustrative embodiment relates to bed locators that provide data and electrical services in a hospital room.

Hospital beds that contain electrically powered equipment can be common, especially in hospitals. Such beds can carry occupant-controlled equipment, such as intercom units, television and lighting remote controls, etc., which receive electrical power via a cord and plug. Also, the beds may need to be positioned such that they line up with critical medical equipment in a hospital room. Beds, especially bigger and heavier beds, such as, bariatric beds, can be prone to damage unprotected walls and other structures. A variety of locators have been designed in the past to assist in the positioning of the bed while helping prevent damage to the walls or other structures. While efforts have been made in the past to enhance the usability of the locators to a user (patient or caregiver), there is still room for improvement. Thus, a need persists for further contributions in this area of technology.

### SUMMARY OF THE DISCLOSURE

The present disclosure comprises one or more of the features recited in the appended claims and/or the following features which, alone or in any combination, may include patentable subject matter:

One illustrative embodiment can include a locator configured to be mounted on a wall and including a protective cover with a lower edge positioned at a height of less than about 10 inches above a floor and a plurality of service outlets positioned at a height of over 22.5 inches above the floor. Other illustrative embodiments can include a locator configured to be mounted on a wall including a protective cover having a width of at least 42 inches and a lower edge positioned at a height of less than about 10 inches above a floor, and a plurality of service outlets positioned at a height of over 22.5 inches above the floor. Still other illustrative embodiment can include a locator configured to be mounted on a wall including a protective cover with lower edge positioned at a height of less than about 10 inches above a floor and an upper edge positioned at least about 26 inches above a lower edge and lower than about 45 inches above a floor, and a plurality of service outlets positioned at a height of over 22.5 inches above the floor.

Additional features alone or in combination with any other feature(s), including those listed above and those listed in the claims and those described in detail below, can comprise patentable subject matter. Others will become apparent to those skilled in the art upon consideration of the following detailed description of illustrative embodiments exemplifying the best mode of carrying out the invention as presently perceived.

### BRIEF DESCRIPTION OF THE DRAWINGS

Referring now to the illustrative examples in the drawings, wherein like numerals represent the same or similar elements throughout:

FIG. 1 illustrates a front view of a locator according to one illustrative embodiment of the disclosure;

FIG. 2 illustrates the top view of the locator of FIG. 1;

FIG. 3 illustrates a front view of a locator used with a headwall according to another illustrative embodiment of the disclosure; and

FIG. 4 illustrates a front view of a locator used with service columns according to still another illustrative embodiment of the disclosure.

### DESCRIPTION OF SPECIFIC ILLUSTRATIVE EMBODIMENTS

One illustrative embodiment can include a locator configured to be mounted on a wall and including a protective cover with a lower edge positioned at a height of less than about 10 inches above a floor and a plurality of service outlets positioned at a height of over 22.5 inches above the floor. Other illustrative embodiments can include a locator configured to be mounted on a wall including a protective cover having a width of at least 42 inches and a lower edge positioned at a height of less than about 10 inches above a floor, and a plurality of service outlets positioned at a height of over 22.5 inches above the floor. Still other illustrative embodiment can include a locator configured to be mounted on a wall including a protective cover with lower edge positioned at a height of less than about 10 inches above a floor and an upper edge positioned at least about 26 inches above a lower edge and lower than about 45 inches above a floor, and a plurality of service outlets positioned at a height of over 22.5 inches above the floor.

While the present disclosure can take many different forms, for the purpose of promoting an understanding of the principles of the disclosure, reference will now be made to the embodiments illustrated in the drawings, and specific language will be used to describe the same. No limitation of the scope of the disclosure is thereby intended. Various alterations, further modifications of the described embodiments, and any further applications of the principles of the disclosure, as described herein, are contemplated.

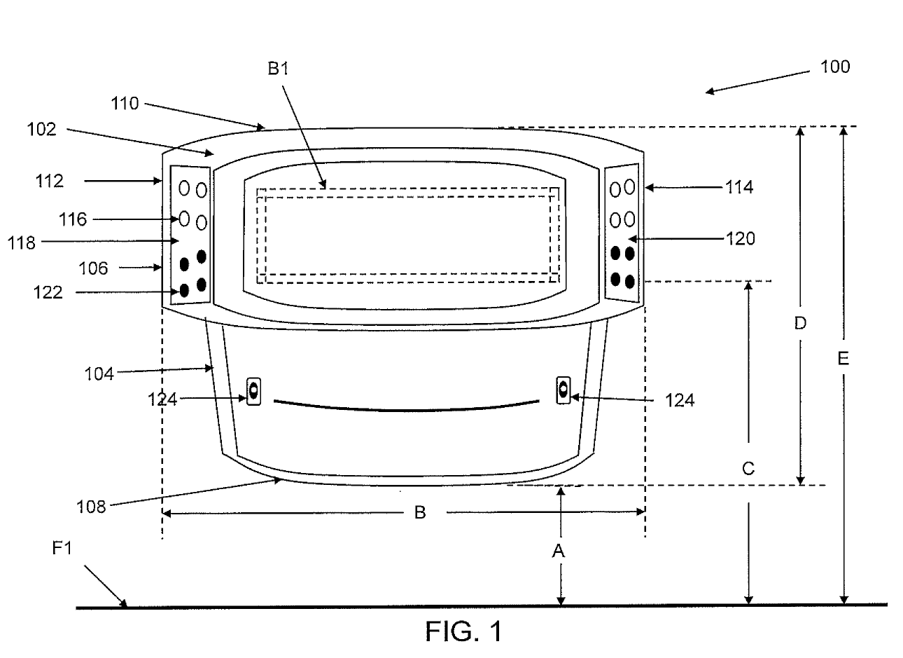

A locator 100 in accordance with one illustrative embodiment of the disclosure is shown in FIG. 1. The locator 100 can include a base B1 and a protective cover 102. The locator 100 can be coupled to a wall W1 via the base B1 and the protective cover 102 can be positioned over the base B1. It should be appreciated that the base B1 can be one or more metal parallelogram structures that can be secured to the wall W1 with fasteners (not shown), such as, screws. It should also be appreciated that the base B1 can be coupled to other structures, such as, a column or a headwall. The locator 100 can assist with locating a hospital bed (not shown) and protecting the wall W1, or other structure the locator 100 is coupled to, from being damaged.

The protective cover 102 can be formed of a single piece as shown in FIG. 1. It should be appreciated that the protective cover 102 can be formed of multiple pieces coupled together. In one illustrative embodiment of the disclosure, the protective cover 102 can be a vacuum formed ABS cover. It should be appreciated that the protective cover 102 can also be a blow molded a-polyethylene or similar material. It should also be appreciated that the protective cover 102 can be a high pressure laminate made of polyethylene.

The protective cover 102 can be a width B and can have a curved shape to minimize protrusions as shown in FIG. 1. The curved design can allow the use of locator 100 with plurality of hospital beds (not shown), stretchers (not shown), and other patient support apparatuses (not shown) of varying width. In one embodiment, the hospital bed (not shown) can be a bariatric bed (not shown), which can be used mainly for obese or overweight people. The widths of bariatric beds can be more than the average sized beds used in the hospitals. In one illustrative embodiment, the protective cover 102 has a width of at least about 45 inches. It should be appreciated that the protective cover 102 can be more or less than 45 inches wide

The cover 102 can include a first cover section 104 or lower cover section 104, a second cover section 106 or upper cover section 106, a lower edge 108, and an upper edge 110 as shown in FIG. 1. The bottom of the first cover section 104 can be defined by the lower edge 108 and the top of the second cover section 106 can be defined by the upper edge 110. The first cover section 104 can be connected to the second cover section 106 and positioned vertically below the second cover section 106. The lower edge 108 can be positioned less than about a distance A above the floor F1. In one illustrative embodiment, the lower edge 108 can be positioned at a height of less than about 10 inches above a floor F1. The upper edge 110 can be positioned at least about a distance D above the lower edge 108, but less than about a distance E above the floor F1. In one illustrative embodiment, the upper edge 110 can be positioned at a height of at least 26 inches above the lower edge 108, but less than about 45 inches above the floor F1. It should be appreciated that the upper edge 110 can be greater than 45 inches above the floor F1.

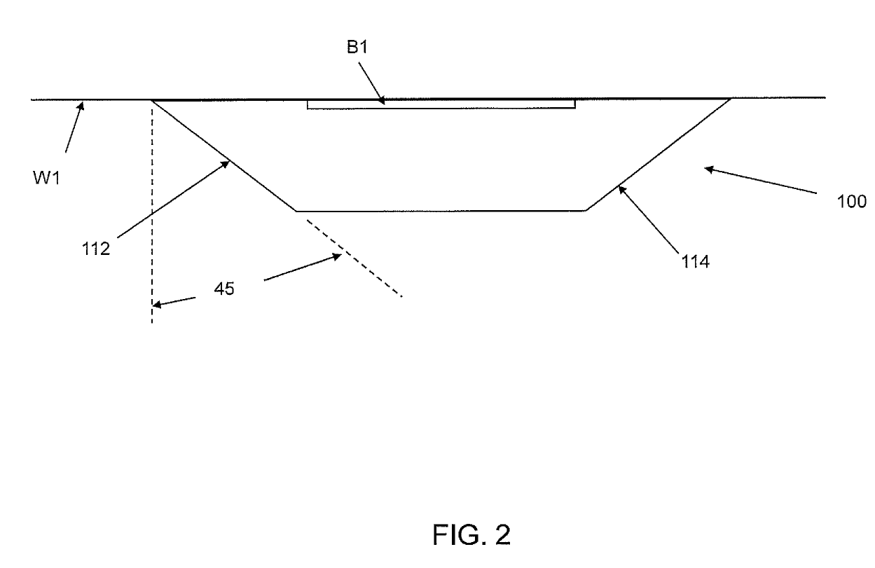

The second cover section 106 can include pair of lateral walls 112 and 114 or sides 112 and 114 that can extend between the upper edge 110 and the first cover section 104 as shown in FIG. 1. It should be appreciated that the sides 112 and 114 can extend between the upper edge 110 and the lower edge 108. The second cover section can include a plurality of medical service outlets 116 positioned on the lateral walls 112 and 114. It should be appreciated that the plurality of medical service outlets 116 can be positioned anywhere on the second section 106. It should also be appreciated that the first cover section 104 can include lateral walls and/or a plurality of medical service outlets. The lateral walls 112 and 114 can be angled at 45° with respect to the wall W1, or other structure the locator 100 is coupled to as shown in FIG. 2. It should be appreciated that the lateral walls 112 and 114 can be any angle with a magnitude of between about 90° and about 0° with respect to the walls of the room. The angle can enhance the accessibility of the plurality of medical service outlets 116 located thereon.

The plurality of medical service outlets 116 can be positioned on each of the lateral walls 112 and 114 at a height C, which can be sufficient to promote easy access by a caregiver to the plurality of medical service outlets 116 without substantial bending of the caregiver as shown in FIGS. 1 and 2. In one illustrative embodiment, the plurality of medical service outlets 116 can be positioned at height of more than 22.5 inches above the floor F1. This height is selected in such a way that it can be in the ergonomic strike zone of the user, which can reduce the bending or stretching of the user while operating the locator 100.

The plurality of medical service outlets 116 can be one or more electrical sockets as shown in FIG. 1. In one illustrative embodiment, the locator 100 can includes four electrical sockets on both sides of the locator 100. These can be used for standard 110V supply and an emergency 110V supply. In addition to the voltage sockets for 110V supply, the locator can contain one or more low voltage sockets which can be provided for connection to electrical equipment such as intercoms, television controls and the like. In another illustrative embodiment, the plurality medical service outlets 116 can also include one or more data ports. The data ports can be connected to a personal computers or an automated device for performing various functions. The locator 100, with its plurality of medical service outlets 116, can enhance the flexibility of the locator 100 and the other equipment surrounding the locator 100.

In one embodiment, the second cover section 106 can include a pair of one piece face plates 118 and 120 as shown in FIG. 1. It should be appreciated that the face plates 118 and 120 can comprise multiple pieces. The face plates 118 and 120 can include holes 122 therein that the medical service outlets 116 are positioned within and/or protrude there from. It should be appreciated that the faceplates 118 and 120 can be positioned over the plurality of medical service outlets 116. The face plates 118 and 120 can be positioned on each of the lateral walls 112 and 114 of the second cover section 106. The face plates 118 and 120 can have a seamless construction, which can allow for enhanced cleanability of the locator 100.

The locator 100 can include an illumination source 124, such as, a light emitting diode (LED), as shown in FIG. 1. The illumination source 124 can be positioned on the first cover section 104. It should be appreciated that the illumination source 124 can also be positioned on the second cover section 106. The illumination sources 124 can be specifically designed for the locator 100 and/or can be molded into the protective cover 102. The illumination sources 124 can create a path of illumination along the side of a person support apparatus (not shown) located by the locator 100, thereby helping identify potential trip hazards while minimizing the amount of light shined on the bed's surface. The Hill-Rom No-Falls™ LED night lights can be used as illumination light sources.

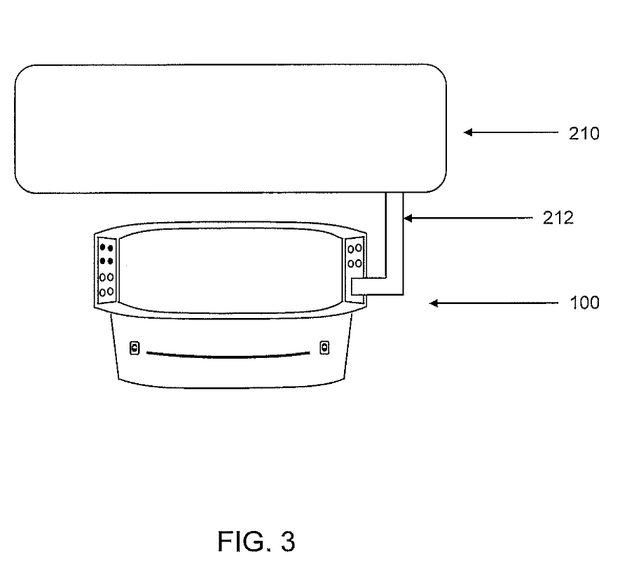

The locator 100 can also be used in combination with other architectural products. In one illustrative embodiment, the locator 100 can be used in combination with a headwall assembly 210 as shown in FIG. 3. The locator 100 can be located below the headwall assembly 210. It should be appreciated that the headwall assembly 210 can be used to provide gas and electrical assistance, as well as other services. It should also be appreciated that the locator 100 can provide gas and electrical power to the headwall assembly 210, or vice versa, through a plurality of conduits 212 or chases 212. The plurality of conduits 212 can extend from the side of the locator 100 and cover cables or hoses running along the surface of the wall WI between the locator 100 and the headwall assembly 210. The plurality of conduits 212 can extend from the face plates 118 and 120. The plurality of conduits 212 can also extend from other parts of the locator 100 to the adjacent structures described above.

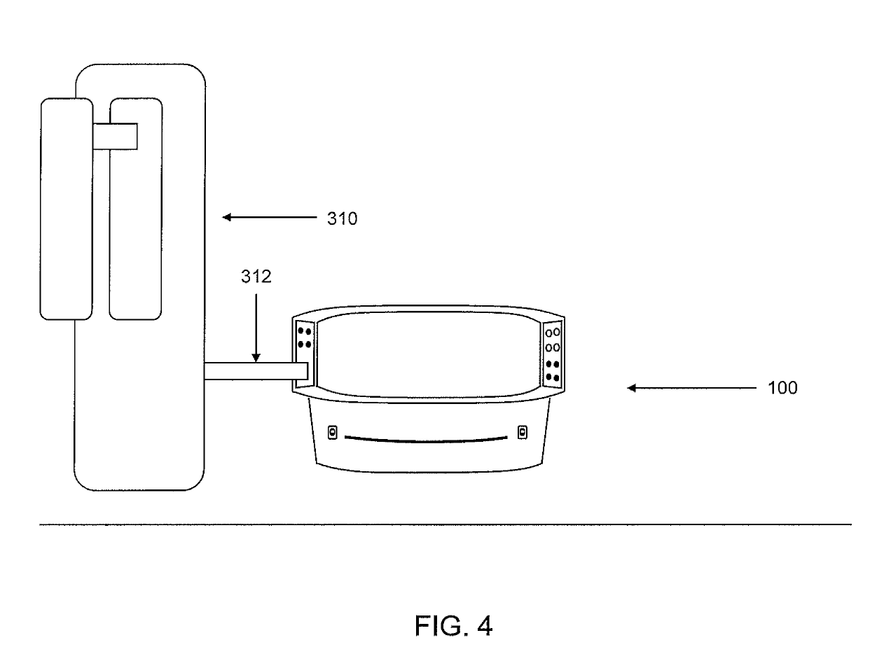

In another illustrative embodiment, the locator 100 can be used with service columns 310 as shown in FIG. 4. The service columns 310 can be attached to the wall WI and can be used provide gas and electrical assistance, as well as other services, and can include various monitoring, lighting, therapy or other medical devices. The locator 100 can provide gas and/or electrical power to the service columns 310, or vice versa, through a plurality of conduits 312 or chases 312. The plurality of conduits 312 can extend from the side of the locator 100 and cover cables or hoses running along the surface of the wall W1 between the locator 100 and the service columns 310. The plurality of conduits 312 can extend from the faceplates 118 and 120. The plurality of conduits 312 can also extend from other parts of the locator 100 to the adjacent structures described above.

Many other embodiments of the present disclosure are also envisioned. For example, a locator comprises a protective cover configured to be mounted on a wall and a plurality of service outlets. The protective cover includes a lower edge. The lower edge is positioned at a height of less than about 10 inches above a floor. The plurality of service outlets are coupled to the protective cover and are positioned at a height of over 22.5 inches above the floor.

In another example, a locator comprises a protective cover configured to be mounted on a wall. The protective cover has a width of at least about 42 inches. The protective cover includes a lower edge and a plurality of service outlets. The lower edge is positioned at a height of less than about 10 inches above a floor. The plurality of service outlets are positioned at a height of over 22.5 inches above a floor.

In yet another example, a locator comprises a protective cover and a plurality of service outlets. The protective cover is configured to be mounted on a wall. The protective cover includes an upper edge and a lower edge. The upper edge is positioned at least about 26 inches above the lower edge and less than about 45 inches above a floor. The lower edge is positioned at a height of less than about 10 inches above a floor. The plurality of service outlets are positioned at a height of over 22.5 inches above a floor.

Any theory, mechanism of operation, proof, or finding stated herein is meant to further enhance understanding of principles of the present disclosure and is not intended to make the present disclosure in any way dependent upon such theory, mechanism of operation, illustrative embodiment, proof, or finding. It should be understood that while the use of the word preferable, preferably or preferred in the description above indicates that the feature so described can be more desirable, it nonetheless can not be necessary and embodiments lacking the same can be contemplated as within the scope of the disclosure, that scope being defined by the claims that follow.

In reading the claims it is intended that when words such as “a,” “an,” “at least one,” “at least a portion” are used there is no intention to limit the claim to only one item unless specifically stated to the contrary in the claim. When the language “at least a portion” and/or “a portion” is used the item can include a portion and/or the entire item unless specifically stated to the contrary.

It should be understood that only selected embodiments have been shown and described and that all possible alternatives, modifications, aspects, combinations, principles, variations, and equivalents that come within the spirit of the disclosure as defined herein or by any of the following claims are desired to be protected. While embodiments of the disclosure have been illustrated and described in detail in the drawings and foregoing description, the same are to be considered as illustrative and not intended to be exhaustive or to limit the disclosure to the precise forms disclosed. Additional alternatives, modifications and variations can be apparent to those skilled in the art. Also, while multiple inventive aspects and principles can have been presented, they need not be utilized in combination, and various combinations of inventive aspects and principles are possible in light of the various embodiments provided above.

What is claimed is:

1. A locator, comprising:
a protective cover configured to be mounted on a wall, the protective cover including a lower edge, the lower edge being positioned at a height of less than about 10 inches above a floor; and
a plurality of service outlets coupled to the protective cover and positioned at a height of over 22.5 inches above a floor.

2. The locator of claim 1, where in the protective cover includes an upper edge, a first section, and a second section, the second section being positioned vertically above the first section, the upper boundary of the second section being defined by the upper edge and the lower boundary of the first section being defined by the lower edge, the second section including sides extending between about the upper edge and about the first section, the plurality of service outlets being coupled to the sides, the sides being angled at a magnitude of about 45° relative to a wall.

3. The locator of claim 1, where in the protective cover includes an illumination source.

4. The locator of claim 3, wherein the illumination source is molded into the protective cover.

5. The locator of claim 1, wherein the protective cover is a single piece protective cover having a curved shape configured to interface with a plurality of person support apparatuses having different widths.

6. The locator of claim 1, wherein the protective cover has antimicrobial properties.

7. The locator of claim 1, wherein the locator includes a conduit that extends from the locator to an adjacent structure.

8. The locator of claim 1, wherein the plurality of service outlets are positioned at a height of between about 26 inches and about 36 inches above a floor.

9. The locator of claim 1, wherein the plurality of service outlets include one or more of electrical sockets and data ports.

10. A locator, comprising:
a protective cover configured to be mounted on a wall, the protective cover having a width of at least about 42 inches, the protective cover including a lower edge and a plurality of service outlets, the lower edge being positioned at a height of less than about 10 inches above a floor and the plurality of service outlets being positioned at a height of over 22.5 inches above a floor.

11. The locator of claim 10, wherein the locator includes a conduit that extends from the locator to an adjacent structure.

12. The locator of claim 11, wherein the adjacent structure is one of a headwall system and a plurality of columns.

13. The locator of claim 10, wherein the protective cover has antimicrobial properties.

14. The locator of claim 10, wherein the plurality of service outlets are positioned at a height of between about 26 inches and about 36 inches above a floor.

15. The locator of claim 10, where in the protective cover includes an illumination source.

16. A locator, comprising:
a protective cover configured to be mounted on a wall, the protective cover including an upper edge and a lower edge, the upper edge being positioned at least about 26 inches above the lower edge and less than about 45 inches above a floor and the lower edge being positioned at a height of less than about 10 inches above a floor; and
a plurality of service outlets positioned at a height of over 22.5 inches above a floor.

17. The locator of claim 16, wherein the plurality of service outlets are positioned at a height less than 36 inches above a floor.

18. The locator of claim 16, wherein the plurality of service outlets are positioned at a height of between about 26 inches and about 36 inches above a floor.

19. The locator of claim 16, wherein the plurality of service outlets include one or more of electrical sockets and data ports.

20. The locator of claim 16, where in the protective cover includes an illumination source.
